(19) United States
(12) Patent Application Publication
(10) Pub. No.: US 2012/0056257 A1
(43) Pub. Date: Mar. 8, 2012

(54) Non-Volatile Memory System with Modified Memory Cells

(75) Inventor: Jeong Y. Choi, Palo Alto, CA (US)

(73) Assignee: MoSys, Inc., Santa Clara, CA (US)

(21) Appl. No.: 12/874,881

(22) Filed: Sep. 2, 2010

(51) Int. Cl. H01L 29/788; H01L 29/92; H01L 21/336; H01L 21/02

(52) U.S. Cl. 257/300; 438/394; 257/532; 438/252; 257/E29.342; 257/E21.008; 257/E21.422; 257/E29.3

(57) ABSTRACT

A method and system in which an embedded memory is fabricated in accordance with a conventional logic process includes one or more non-volatile memory cells, each having an access transistor and a capacitor, which share a common floating gate electrode. The coupling capacitor is provided with a dielectric layer having a thickness greater than the dielectric layer of the access transistor. Regions under the capacitor are implanted with a high dose implant to form an electrically shorted doped area in the channel region of the capacitor. The high dose implant improves the coupling ratio of the capacitor and enhances the uniformity of the capacitor's oxide layer.

### BACKGROUND

In the semiconductor industry foundries have developed standard logic processes that intellectual property (IP) vendors use to combine with specialty technologies. Design houses reuse the same system-on-a-chip (SoC) design with or without any specialty IP (e.g., DRAM or nonvolatile memory). It is important to maintain a consistent process for fabricating the logic devices regardless of whether IP components are integrated into the process. Nevertheless, many IP components have been developed with minor (but critical to some applications) modification of logic devices, with increased sizes (and thus defeating the effort of miniaturization to a certain degree), or with a higher cost of manufacturing.

In some nonvolatile memories charge is stored in a floating gate. Data is stored in the memory cell by injecting electrons into, or removing electrons from, the floating gate. Specifically, the charge is programmed into the floating gate by application of a high voltage between a semiconductor layer (having a channel) and the control gate. Data is erased in a nonvolatile memory when charge is extracted from the floating gate. Application of a high voltage to the memory causes Fowler-Nordheim (F-N) tunneling or hot-carrier injection through the insulating layer that is adjacent to the channel formation region. This insulating layer contacts the substrate and is referred to as a tunnel oxide.

The electrons in the floating gate may leak during standby or read operations (during which the memory is biased at much lower voltages than during program or erase operations) if the oxide thickness is substantially nonuniform at certain locations within the device. This charge loss can result in data inversion leading to numerous errors that may not be detected during manufacturing or wafer sort testing. Charge loss can be reduced by increasing the thickness of the tunnel oxide layer. However, a thick oxide layer can also impair the functionality of the memory, e.g. by requiring a device (such as a diode or MOSFET) to support erase or program biases with the highest possible breakdown voltage. Also, thick insulating layers are not compatible with the logic area of the device. Typically, the logic area must have a thin oxidation layer to enable the device to operate at optimal speeds.

Programmed cells have a higher voltage drop across the capacitor dielectric than across the tunnel oxide of the access transistor. By contrast, erased cells experience a greater voltage drop across the tunnel oxide than across the capacitor dielectric. Since the greatest charge loss in programmed cells occurs through the capacitor dielectric, a thicker capacitor dielectric will improve the reliability of non-volatile memories. To counteract the charge loss due to the greatest voltage drop in erased cells, a common practice is to weakly erase cells. In addition, the voltage drop across the tunnel oxide of an erased cell can be reduced below the voltage drop across the capacitor dielectric of programmed cells by weakly erasing and strongly programming the cells for normal operation. As can be appreciated, the various methods for reducing the effects of charge loss in a non-volatile memory are complex and dependent on the primary type of operation that is most frequently performed in the affected memory.

The current methods for preventing charge loss in non-volatile memories (NVM) are inadequate. Therefore, a need exists for a nonvolatile memory cell that is compatible with a logic process and that has a reduced amount of charge leakage. In addition, a simpler way of reducing charge loss is desirable without limiting the cell to a specific number of programming or erase operations. A need also exists to optimize the coupling ratio of the cell so that erase, read and programming operations are not impaired when the cell is embedded in a logic circuit.

### SUMMARY OF THE INVENTION

The present invention provides a high-density nonvolatile memory that has a high coupling ratio with only minimal changes to the conventional logic process.

The present invention is primarily applicable to a nonvolatile memory cell having a single polysilicon layer. However, the present invention is also applicable to a nonvolatile memory having multiple polysilicon layers. In addition, the present invention is applicable to any memory device that may require an oxide thickness that is different from that of logic devices. The invention may also be used to improve the performance, functionality, cost, and/or reliability of a product that incorporates a memory within it.

The memory cell of the invention has an access transistor and a capacitor that are fabricated from a single polysilicon layer. The dielectric layer of the capacitor is thicker than the gate dielectric layer of the access transistor.

### BRIEF DESCRIPTION OF THE DRAWINGS

FIGS. 1A-1E illustrate a process for fabricating a nonvolatile system with different oxide thicknesses in accordance with the present invention.

FIGS. 2A-2C illustrate cross-sectional views of the nonvolatile memory system in accordance with the present invention.

### DETAILED DESCRIPTION OF THE INVENTION

This invention is for a single polysilicon process for a nonvolatile memory cell and system that is compatible with a conventional logic process. As used herein, a conventional logic process is defined as a single- or multiple-well process with a single polysilicon layer and at least one metal layer. The memory cell in the figures below is composed of a PMOS-based cell that includes a PMOS access transistor and an NMOS capacitor. However, in another embodiment of the invention the conductivity types of the various elements can be reversed. Accordingly, the present invention is also applicable to an NMOS-based cell composed of an NMOS access transistor and a PMOS capacitor. The capacitor may have a dielectric layer of greater thickness than the gate oxide of the access transistor to prevent charge loss. The capacitor may be doped with a high dose implant to improve its coupling ratio and the associated uniformity of the memory cell behavior.

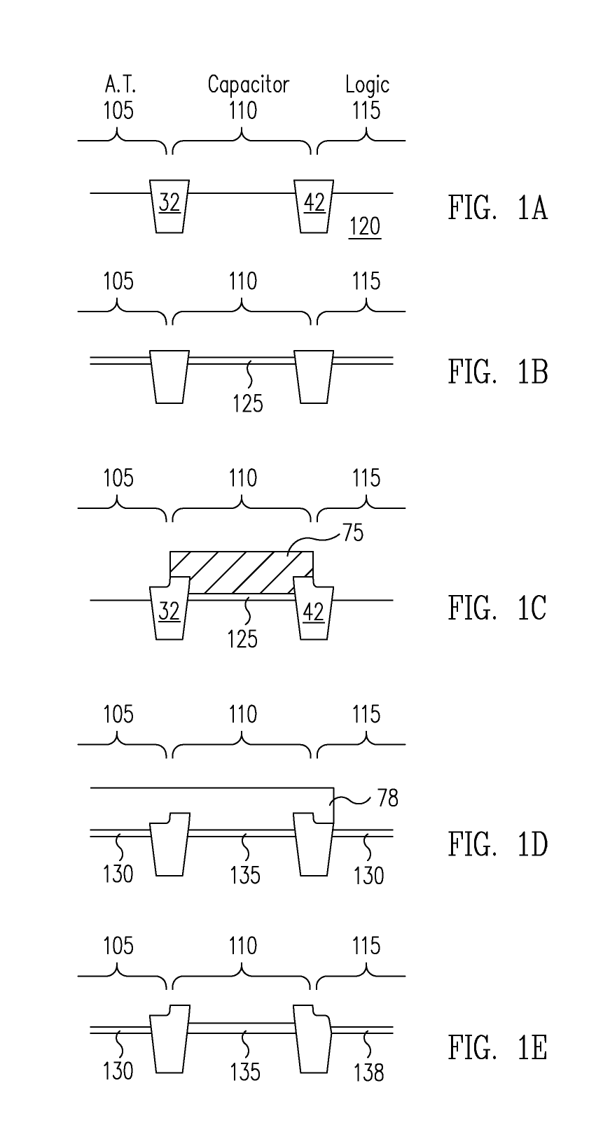

The process of the invention will be more easily understood in reference to the figures. FIGS. 1A-1E illustrate one possible sequence for forming the oxide layers within the non-volatile memory cell. FIG. 1A illustrates a partially-completed semiconductor structure containing an access transistor area 105 separated from a capacitor area 110 by shallow trench isolation (STI) region 32. The capacitor area 110 is separated from logic area 115 by STI region 42. In reality, the logic area surrounds the memory array. In other words, logic area 115 can also occupy the area adjacent to access transistor area 105 in addition to, or instead of, the location shown in FIG. 1A. The STI regions 32 and 42 are formed within silicon substrate 120. A first gate oxide layer 125 is grown above substrate 120 using thermal oxidation to form the structure of FIG. 1B. Next, a photoresist mask 75 is disposed over the area that will become the capacitor to protect the underlying oxide layer 125 as shown in FIG. 1C. The unprotected oxide layer and upper corners of isolation regions 32 and 42 are etched away. Afterwards, the photoresist mask 75 is removed, and a second oxide layer is grown forming oxide layer 130 in the access transistor area 105 and the logic area 115. Both of the oxide layers 130 are grown to have substantially the same thickness. The oxidation step of FIG. 1D increases the oxide layer thickness in the capacitor area 110 to produce a structure having a thicker oxide layer 135 in the capacitor area 110 than in the logic 115 and other memory areas 105. Next with mask 78, oxide 130 in the logic area 115 is removed. Then a third oxidation step is performed to increase the thickness of the remaining oxide layers 130 and 135, while growing a thin oxide layer 138 in logic area 115 to produce the structure of FIG. 1E. Oxide layer 135, in the capacitor area, will be approximately 30-100 Angstroms thicker than oxide layer 130. Afterwards polysilicon gates are formed in both the memory and logic areas using a conventional chemical vapor deposition process.

One disadvantage of having a thicker dielectric for the capacitor is the reduction in the cell coupling ratio. A reduced coupling ratio will impact the cell's operation differently depending on whether data is being erased or programmed. For example, an erase operation typically requires higher voltages and/or longer time periods. For program and read operations for which the coupling ratio is determined by the lateral diffusion of LDD implant for the capacitor, there will be a significant increase in the fluctuation of the coupling ratio. This larger fluctuation adversely impacts the reliability of the memory cells. To ensure a proper read operation of the cells with the lowest coupling ratio, the program strength must be substantially increased, thereby causing cell leakage and failure of the cells during use. Failures caused by fluctuations in the coupling ratio pose difficult problems for advanced technologies when shallow LDD implants are present. Shallow LDD implants are often used as devices are scaled downward and may not wholly penetrate the thicker capacitor dielectrics. To overcome this shortcoming, the present invention introduces an implant into the LDD region of the capacitor, thereby ensuring consistent drain-to-gate overlap for the capacitor. The present invention protects the differential oxide thickness of FIG. 1E by using the polysilicon gates as masks. Specifically the polysilicon gates protect the underlying oxide layers 130, 135 from implant damages and processing chemicals. At the gate edges of the gate oxide there may be slight damage due to ion traps, which can be resolved by annealing.

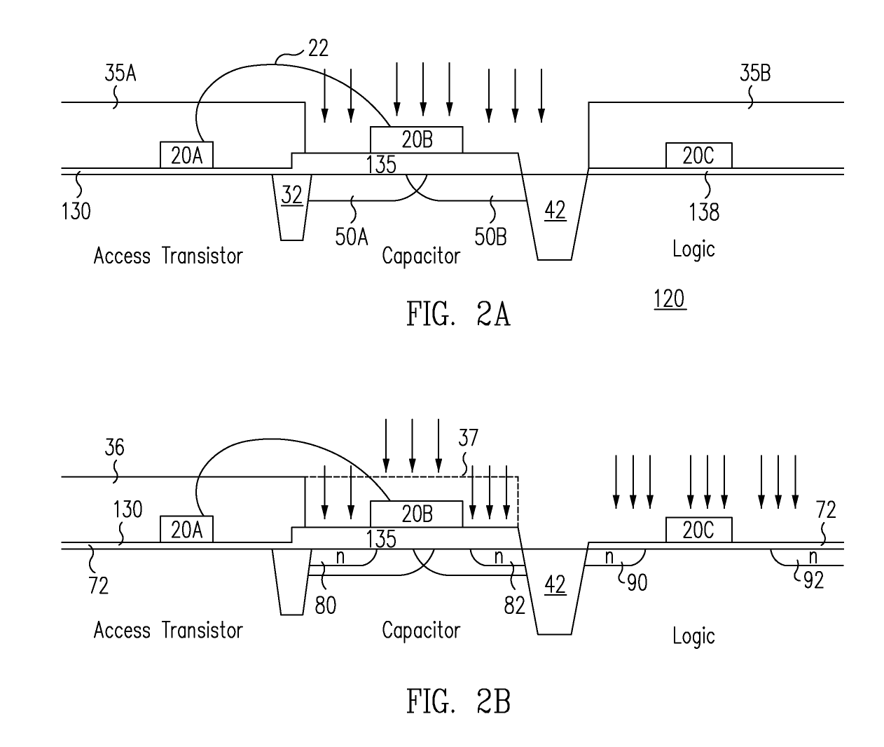

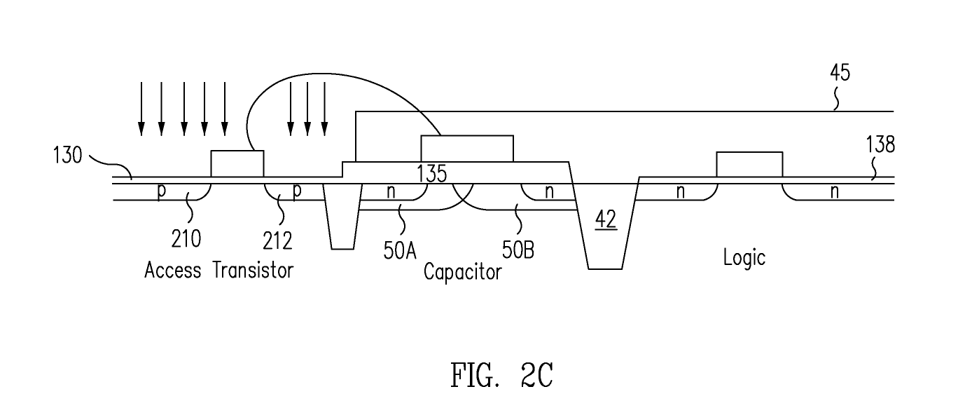

FIG. 2A illustrates a partially completed semiconductor substrate that includes three active areas isolated from each other by shallow trenches. For clarity and simplicity, trenches 32 and 42 are shown with a planar upper surface. However, it is understood that trenches 32, 42 in FIGS. 2A-2C resemble trenches 32, 42 of FIG. 1C. In FIG. 2A, access transistor is separated from the capacitor area by trench 32, and the capacitor is separated from the logic area by trench 42. The capacitor and the access transistor share a single continuous polysilicon layer. The continuous polysilicon layer in FIG. 2A is shown as two separate gates 20A and 20B connected by a link 22. The single poly gate is formed by a conventional process prior to the ion implantation step of FIG. 2A. FIG. 2A also illustrates a structure having differential oxide layers 130, 135 and 138. These oxide layers were formed in accordance with the process set forth in FIGS. 1A-1E.

In FIG. 2A, mask 35A is placed over a portion of the continuous polysilicon gate (20A) to protect the access transistor, and mask 35B is placed over gate 20C to protect the logic area. Then an n-type dopant is implanted at a dosage level between 1×10¹³ to 5×10¹⁵ atoms/cm² and an implant energy of 10100 keV into the capacitor region. Suitable n-type dopants for this step include arsenic and phosphorus ions. Because the n-type ions are implanted at a high dosage, the implanted ions laterally diffuse into the channel of the capacitor below dielectric layer 135. Consequently, the doped regions 50A and 50B under the capacitor diffuse toward each other, forming an electrically connected region within the channel located between trenches 32 and 42. This doped channel region increases the coupling ratio of the memory cell. Ideally, the line width of 20B should be small enough to allow the regions 50A and 50B to merge, so that the entire capacitor area may contributes to coupling. Alternatively, the implant may be performed at an angle to increase the overlap of 50A and 50B in the channel. Next, the access transistor and PMOS transistors in logic region are covered by a mask 36. An n-type dopant is implanted into the exposed areas to form lightly doped source/drain regions 80 and 82 in the capacitor and lightly doped source/drain regions 90 and 92 in the logic area. Then a second implant is provided as shown in FIG. 2B. Specifically, an n-type dopant is implanted at a dosage level of approximately 1×10¹³ to approximately 1×10¹⁵ atoms/cm² and an implant energy of 10100 keV. This second implant is typically performed at a lower energy level than the first implant, because the second implant is optimized for forming thin-oxide logic devices, while the first implant is optimized for forming thick-oxide capacitors. In some embodiments, the capacitor in FIG. 2B may also be covered by mask 37 during this step. After the implantation step of FIG. 2B, mask 36 (or mask 37) is removed. Then, mask 45 is placed over the capacitor and logic areas as shown in FIG. 2C to permit a p-type ion implantation. Suitable p-type dopants include boron and indium. The p-type ions are implanted at a dosage level of between approximately 1×10¹² to approximately the order of 1×10¹⁴ atoms/cm² to form lightly doped source/drain regions 210, 212 for the access transistor. Thereafter, sidewall spacers are formed on the select gate and logic gate in a manner that is well known in the art. A dielectric layer is then conformally deposited over the gates, followed by a passivation layer. The resulting nonvolatile semiconductor structure exhibits a better coupling ratio than other embedded nonvolatile memory structures.

In a less preferred embodiment, the high dose implant of FIG. 2A may be performed prior to growing silicon oxide layer 130. However, performing the high dose implant early will cause the n-type ions to damage the unprotected silicon substrate. Such damage may propagate into the oxide when the oxide layer is later grown on the silicon.

To remedy damage caused by a high-dose ion implantation prior to gate formation, the high-dose implant is preferably followed by a comprehensive annealing step. The annealing step is preferably performed at 900-1200° C. for a period of 30-60 minutes. Subsequently, the structure of FIG. 2A is annealed for 24 hours at 500-700° C. However, this annealing may result in diffusion of the high-dose implant into the isolation regions.

The present invention as described above increases the coupling ratio by using a high-dose implantation. This in turn improves the operating window of the device by providing a sharper distinction between the erase and programming signals. The increased coupling ratio of the present invention enables the memory to be programmed and erased at a faster speed. Thus, the embedded flash memories of the present invention demonstrate improved performance over the flash memories in the prior art.

In addition to performance advantages, the present invention also provides size and reliability advantages. The higher coupling ratio produced by the capacitor implant enables a smaller capacitor to be used without significantly affecting the operation window, resulting in a smaller memory cell.

Further, a higher coupling ratio makes it unnecessary to program the cells as strongly as for a cell without the implant (i.e. since the charge density on the floating gate is lower, the cells of the present invention are more reliable). The present invention reduces the electric field across the capacitor dielectric, thereby improving the overall reliability of the memory cell.

The present invention has been described using an exemplary process flow. However, the aforementioned examples are illustrative only and are not intended to limit the invention in any way. For example, it is not necessary to rely on pure oxide layers to perform any or all of the oxidation steps of the present invention. Any of the oxidation steps may instead incorporate nitrogen or use high-K dielectrics to produce the dielectric layers of the present invention. In the above description, an exemplary process flow has been discussed for forming differential oxide thicknesses. However, it is possible to form the differential oxide thicknesses using other types of processes, including oxidation-enhancing implants. The skilled artisan would readily appreciate that the examples above are capable of various modifications. Thus, the invention is defined by the claims set forth below.

What is claimed is:

1. A method of forming an embedded non-volatile memory system using a conventional logic process comprising:
fabricating an access transistor gate with a thin dielectric layer; and
fabricating a coupling capacitor with a thick dielectric layer having a thickness greater than the thin dielectric layer.

2. The method of claim 1, wherein the thick dielectric layer is at least about 30 percent thicker than the thin dielectric layer.

3. The method of claim 1, wherein the thin dielectric layer has a thickness in the range of about 40 to 80 Angstroms, and wherein the thick dielectric layer has a thickness in the range of about 70 to 150 Angstroms.

4. The method of claim 1, further comprising the step of implanting dopant into a channel region of the coupling capacitor after a gate layer of the coupling capacitor has been formed.

5. The method of claim 4, wherein the step of implanting is performed at an angle between 5 and 45 degrees.

6. A method of forming a non-volatile memory cell comprising:
fabricating an access transistor of the non-volatile memory cell with a thin gate dielectric layer of a logic process; and fabricating a coupling capacitor of the non-volatile memory cell with a thick dielectric layer, wherein the thin gate dielectric layer is also used to fabricate transistors external to the non-volatile memory cell.

7. The method of claim 6, wherein the thick dielectric layer is at least about 30 percent thicker than the thin gate dielectric layer.

8. The method of claim 6, further comprising selectively implanting a dopant at high dosage levels into the capacitor area to form a laterally diffused doped region under the dielectric layer of the capacitor area.

9. The method of claim 6, wherein the thin gate dielectric layer has a thickness in the range of about 40 to 80 Angstroms, and wherein the thick gate dielectric layer has a thickness in the range of about 70 to 150 Angstroms.

10. A nonvolatile memory cell having a single polysilicon layer comprising:
an access transistor with a thin dielectric layer; and a coupling capacitor with a thick dielectric layer having a thickness greater than the dielectric layer of the access transistor.

11. The nonvolatile memory cell of claim 10, wherein the access transistor and coupling capacitor share a single continuous polysilicon layer.

12. The nonvolatile memory cell of claim 10, wherein the thick dielectric layer is 20-35% thicker than the thin gate dielectric layer.

13. The nonvolatile memory cell of claim 10, wherein the thin dielectric layer has a thickness in the range of about 40 to 80 Angstroms and wherein the thick dielectric layer has a thickness in the range of 70-150 Angstroms.

14. The nonvolatile memory cell of claim 10, wherein the thin dielectric layer and the thick dielectric layers are selected from the group consisting of hafnium oxide, oxynitride or silicon nitride.

15. A non-volatile memory system including memory cells and logic transistors on the same semiconductor substrate, wherein a floating gate is shared by both access transistors and coupling capacitors within the memory cell, the system comprising:
an access transistor having source/drain regions in the substrate, and a channel between the source and drain regions, said channel being separated from the floating gate by a gate dielectric layer;
a coupling capacitor having source/drain regions and a channel in the substrate, said channel being separated from the floating gate by a thick dielectric layer, wherein the thick dielectric layer of the coupling capacitor has a thickness greater than the thickness of the gate dielectric layer of the access transistor.

16. The system of claim 15 wherein the source/drain regions of the coupling capacitor are electrically coupled within the channel.

17. The system of claim 15, wherein the thin gate dielectric layer has a thickness in the range of about 40 to 80 Angstroms, and wherein the thick dielectric layer has a thickness in the range of about 70 to 150 Angstroms.

18. The system of claim 15, further comprising a logic transistor having a dielectric layer formed concurrently with the formation of the gate dielectric layer of the access transistor.

19. A method of forming a nonvolatile memory cell having an access transistor and a capacitor structure within a semiconductor substrate, the method comprising:
forming an insulating layer on the semiconductor substrate;
forming an access transistor gate and a logic gate on the insulating layer;
forming a capacitor between the gates on the insulating layer;
providing a first mask on portions of the insulating layer to thereby expose the capacitor area;
ion implanting an impurity of a first conductivity type at a high dosage level into the capacitor area;
removing the first mask;
providing a second mask on the upper surface of the semiconductor substrate to expose only the access transistor gate; and
ion implanting an impurity of a second conductivity type at a low dosage level to form doped regions in the access transistor.

20. The method of claim 19, wherein prior to forming doped regions in the access transistor, a photoresist is provided over the access transistor and an impurity of the first conductivity type is implanted into the substrate to form source/drain regions in the logic area and the capacitor area.

21. The method of claim 19, wherein prior to forming doped regions in the access transistor, a photoresist is provided over both the access transistor and the capacitor, and an impurity of the first conductivity type is implanted into the substrate to form source/drain regions in the logic area and the capacitor area.

22. The method of claim 19, wherein the insulating layer comprises a dielectric layer in the capacitor area that is greater in thickness than the access transistor gate.

23. The method of claim 19, wherein the thick dielectric layer is at least about percent thicker than the access transistor gate.

24. The method of claim 19, wherein the high dosage implant is implanted at a dosage of 1×10¹⁴ atoms/cm² to 5×10′⁵ atoms/cm².

25. The method of claim 19, wherein the low dosage implant is implanted at a dosage of 1×10¹² to 1×10¹⁴ atoms/cm².

26. A method of forming an embedded nonvolatile memory system including nonvolatile memory cells and logic transistors on a semiconductor substrate, each of the nonvolatile memory cells having an access transistor and a capacitor area, the method comprising:
forming shallow trench isolation regions in the semiconductor substrate;
forming an insulating layer on the semiconductor substrate;
forming gates for memory and logic devices on the insulating layer;
disposing a first mask on portions of the insulating layer to expose the capacitor area;
implanting an impurity of a first conductivity at a high dosage level into the capacitor area;
removing the first mask;
providing a second mask on the upper surface of the semiconductor substrate to expose only the access transistor; and
implanting an impurity of a second conductivity type at a low dosage level to form doped regions in the access transistor.

27. The method of claim 26, wherein prior to forming doped regions in the access transistor, a photoresist is provided over the memory cell and an impurity of the first conductivity type is implanted into the logic area and the capacitor area.

28. The method of claim 26, wherein the high dosage implant is implanted at a dosage of 1×10¹³ atoms/cm² to 5×10′⁵ atoms/cm².

29. The method of claim 26, wherein the low dosage implant is implanted at a dosage of 1×10¹² atoms/cm² to 1×10¹⁴ atoms/cm².
